(19) United States
(12) Patent Application Publication
(10) Pub. No.: US 2005/0266657 A1
(43) Pub. Date: Dec. 1, 2005

(54) Substrate manufacturing method

(75) Inventor: Ryuji Moriwaki, Zama (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/139,484

(22) Filed: May 31, 2005

(30) Foreign Application Priority Data
May 31, 2004 (JP) 2004-161565

(51) Int. Cl. H01L 27/01; H01L 27/12; H01L 31/0392; H01L 21/30; H01L 21/46

(52) U.S. Cl. 438/455

(57) ABSTRACT

A first substrate which has a semiconductor and an insulating layer formed on the surface of the semiconductor is prepared. The periphery of the insulating layer is selectively removed to expose the semiconductor. The first substrate on the insulating layer side is bonded to a second substrate to form a bonded substrate stack.

### FIELD OF THE INVENTION

The present invention relates to a substrate manufacturing method and, more particularly, to a method of manufacturing an SOI substrate whose insulating film is not exposed to the side surface.

### BACKGROUND OF THE INVENTION

Several methods of manufacturing an SOI substrate by bonding have been disclosed. Three representative methods will be described below.

In the first method, two substrates are bonded while inserting an oxide film between them. Polishing and grinding are performed from one side to leave a substrate having a desired thickness on the oxide film. Based on this technique, several methods of thinning a substrate with high controllability have been proposed.

The second method uses porous Si (Japanese Patent Laid-Open No. 5-21338). In this method (ELTRAN (registered trademark)), an epitaxial Si layer grown on a porous Si substrate is bonded to a support substrate while inserting an oxide film between them. After annealing is executed to increase the bonding strength, the structure is cleaved and split by an external force along stress in the porous Si layer. The porous Si layer remaining on the surface of the layer transferred to the support substrate side is selectively etched, thereby obtaining an SOI substrate. In this method, a similar SOI substrate can also be obtained by grinding the bonded substrate stack from the lower surface on the porous layer formation side to expose the porous Si layer and then selectively etching the porous layer.

The third method uses hydrogen ion implantation (Japanese Patent Laid-Open No. 5-211128). In this method (Smart Cut (registered trademark)), an oxide film is formed on at least one of two Si substrates. In addition, hydrogen ions or rare gas ions are implanted from the upper surface of one Si substrate to form a micro-bubble layer (enclosed layer) in the substrate. After that, the ion-implanted surface is bonded to the other Si substrate (support substrate) while placing the oxide film between them. Annealing is executed to peel one substrate thin from the micro-bubble layer serving as a cleavage plane. Annealing (bonding annealing) is further executed to increase the bonding strength, thereby obtaining an SOI substrate.

SOI substrates manufactured by the first to third methods have the same structure in which the insulating film (SiO₂) is finally exposed to the periphery. As a result, the insulating film (SiO₂) exposed to the periphery of the SOI substrate is selectively etched in, e.g., manufacturing a semiconductor device. The Si layer on the surface overhangs like a terrace, and the strength becomes low. This may cause chipping so that Si fragments can damage the wafer surface, and the yield of high-quality semiconductor devices may decrease.

AN SOI substrate is demanded in which the side surface of the oxide film is covered with single-crystal Si so that any adverse effect of the insulator on the process can be prevented. To cover the side surface of the oxide film of an SOI substrate with single-crystal Si, a first substrate having a flat surface and an oxide film at the central portion of the surface must be prepared and bonded to a second substrate.

In a technique disclosed in Japanese Patent Laid-Open No. 8-195483, the periphery of an Si substrate is masked by an Si₃N₄ film. After the central portion of the Si substrate is oxidized, the surface is polished, thereby forming a first substrate having a flat surface and an oxide film at the central portion of the surface. The first substrate is bonded to a second substrate to manufacture an SOI substrate.

In Japanese Patent Laid-Open No. 8-195483, however, until formation of the first substrate having the flat surface and the oxide film at the central portion of the surface, a number of complex processes must be executed, including the process of forming the Si₃N₄ film on the entire surface of the substrate, the process of etching the central portion of the Si₃N₄ film to form the mask, annealing of the unmasked central portion, mask removal, and polishing.

### SUMMARY OF THE INVENTION

The present invention has been made in consideration of the above-described problems, and has as its object to provide a method of manufacturing an SOI (Semiconductor On Insulator) substrate whose insulating film is not exposed to the side surface by a few simple processes.

According to the present invention, there is provided a substrate manufacturing method comprising steps of preparing a first substrate which has a semiconductor and an insulating layer formed on a surface of the semiconductor, selectively removing a periphery of the insulating layer to expose the semiconductor, and bonding the first substrate on a side of the insulating layer to a second substrate to form a bonded substrate stack.

According to the present invention, an SOI (Semiconductor On Insulator) substrate whose insulating layer has a side surface covered with a semiconductor layer can be implemented by a few simple processes.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1A to 1F are sectional views schematically showing the first embodiment and Example 1 of an SOI substrate manufacturing method according to the present invention;

FIGS. 2A to 2G are sectional views schematically showing the second embodiment and Example 2 of an SOI substrate manufacturing method according to the present invention;

FIGS. 3A to 3F are sectional views schematically showing the third embodiment and Example 3 of an SOI substrate manufacturing method according to the present invention;

FIG. 4 is a view schematically showing the first method of selectively removing the periphery of an insulating layer;

FIG. 5 is a view schematically showing the second method of selectively removing the periphery of an insulating layer; and

FIG. 6 is a view schematically showing the third method of selectively removing the periphery of an insulating layer.

### DETAILED DESCRIPTION OF THE PREFERRED EMBODIMENTS

The preferred embodiments of the present invention will be described below in detail with reference to the accompanying drawings.

[First Embodiment]

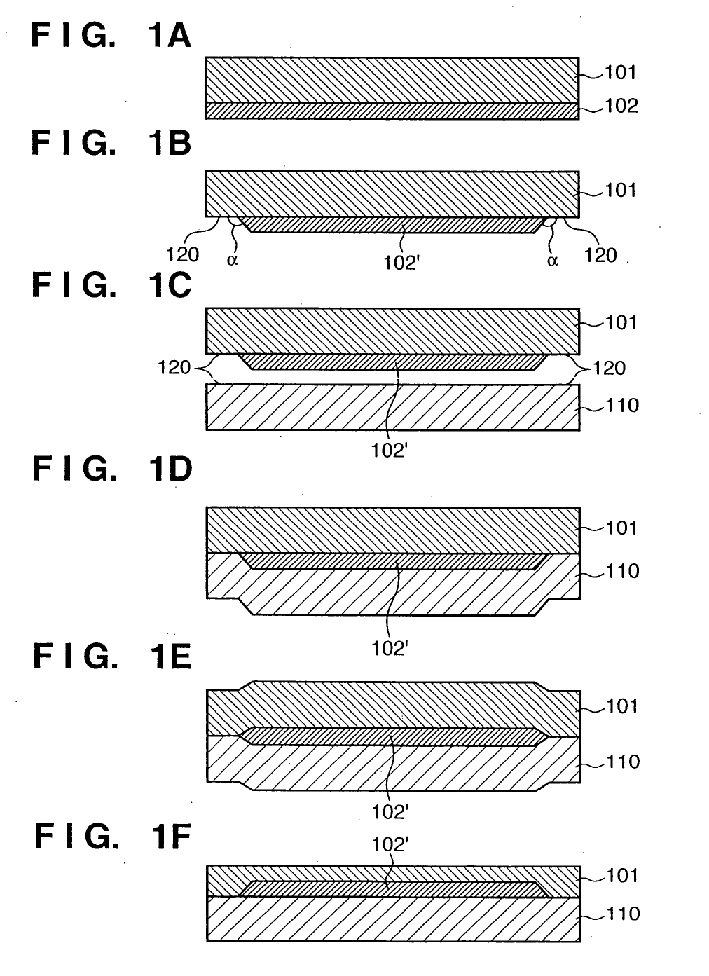

A substrate manufacturing method according to the first embodiment of the present invention will be described below. FIGS. 1A to 1F are sectional views showing the substrate manufacturing method according to the first embodiment of the present invention.

In the step shown in FIG. 1A, a first substrate 101 is prepared. An insulating layer 102 is formed on the major surface of the first substrate 101. As the first substrate 101, a semiconductor such as Si such as single-crystal silicon, polysilicon, or amorphous silicon, Ge, SiGe, SiC, C, GaAs, GaN, AlGaAs, InGaAs, InP, or InAs is preferable. As the insulator material of the insulating layer 102, for example, silicon oxide, silicon nitride, silicon oxynitride, aluminum oxide, tantalum oxide, hafnium oxide, titanium oxide, scandium oxide, yttrium oxide, gadolinium oxide, lanthanum oxide, zirconium oxide, or a mixture or glass thereof is preferable. The insulating layer 102 can be formed by, e.g., oxidizing the surface of the first substrate 101 or depositing an insulator substance by CVD or PVD. If the first substrate 101 or second substrate 110 contains an insulator in its surface, the step of forming the insulating layer 102 may be omitted.

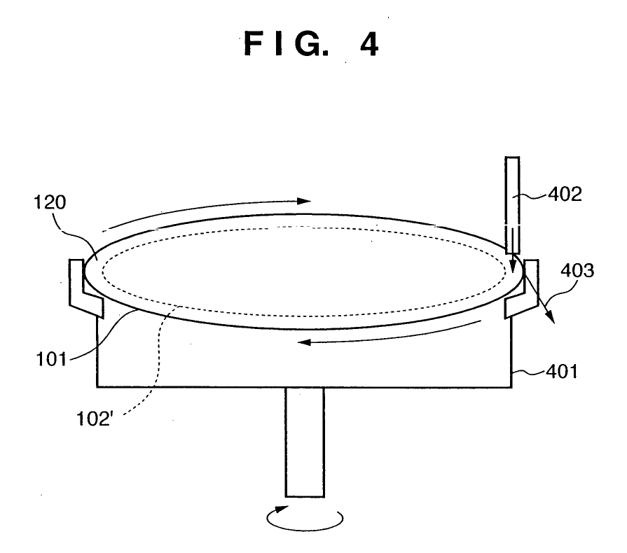

In the step shown in FIG. 1B, a periphery 120 of the insulating layer 102 is selectively removed to expose the first substrate 101. The periphery 120 of the insulating layer 102 can selectively be removed by, e.g., the methods shown in FIGS. 4 to 6.

FIG. 4 is a view schematically showing the first method of selectively removing the periphery 120 of the insulating layer 102. The first substrate 101 is placed on a spinner 401 and rotated at a predetermined rotational speed. As the first substrate 101 rotates, an etching solution 403 such as an HF solution to etch the oxide film is supplied from a nozzle 402 to the periphery 120 of the first substrate 101. Since the etching solution 403 moves outward from the first substrate 101 because of the centrifugal force, the central portion of the first substrate 101 is not etched. When the periphery 120 of the first substrate 101 is etched while rotating the first substrate 101, an insulating layer 102′ can be formed at the central portion (region except the periphery 120) of the first substrate 101.

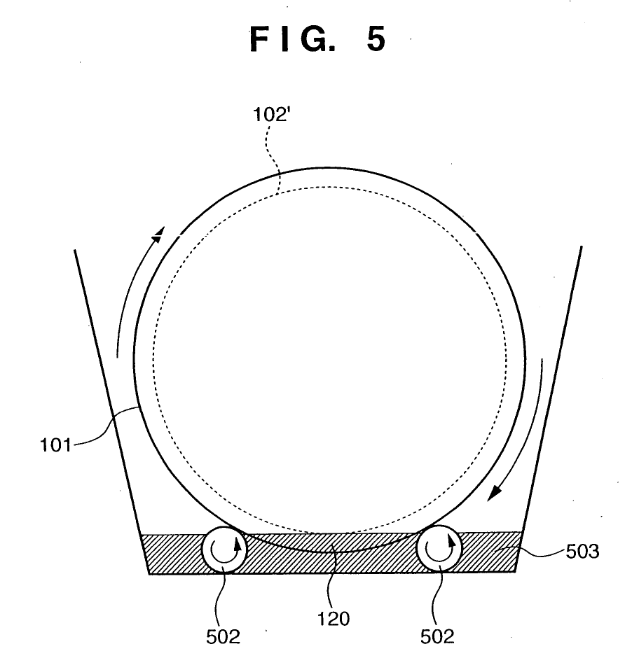

FIG. 5 is a view schematically showing the second method of selectively removing the periphery 120 of the insulating layer 102. The first substrate 101 is placed almost vertically on wafer rotating rollers 502 in a chemical solution tank 501. The wafer rotating rollers 502 have a groove to support the first substrate 101. When the wafer rotating rollers 502 rotate, the first substrate 101 rotates. An etching solution 503 such as an HF solution to etch the oxide film is supplied into the chemical solution tank 501. The etching solution 503 is supplied so that the periphery 120 of the first substrate 101 is barely dipped in it.

To prevent the etching solution 503 from reaching parts except the periphery 120 during rotation of the first substrate 101, for example, the following two methods are available. In the first method, the etching solution 503 such as hydrofluoric acid with a high etching selectivity between the first substrate 101 and the insulating layer 102 is used, and the rotational speed of the first substrate 101 is reduced as much as possible (e.g., 1 revolution per hr). Since the insulating layer 102 is completely etched, overetching causes no problem. More specifically, since the etching selectivity between the first substrate 101 and the insulating layer 102 is high, the first substrate 101 is rarely etched. In the second method, a cover rinse such as pure water is sprayed to the central portion of the surface of the first substrate 101. At the same time, the etching solution 503 is supplied to the chemical solution tank 501 to prevent dilution of the etching solution 503. In this case, since the insulating layer 102 is completely etched, the concentration of the etching solution 503 is rarely influenced.

When the periphery 120 of the first substrate 101 is dipped in the etching solution 503, and the first substrate 101 is rotated, the insulating layer 102′ can be formed at the central portion of the first substrate 101.

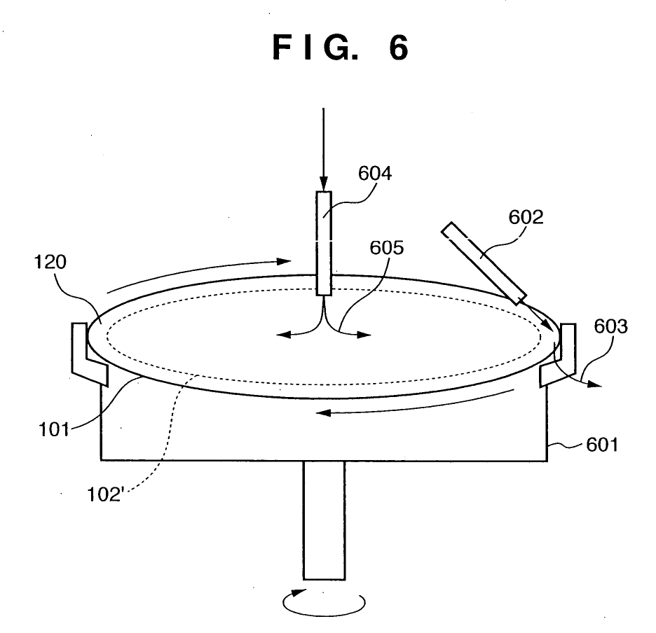

FIG. 6 is a view schematically showing the third method of selectively removing the periphery 120 of the insulating layer 102. The first substrate 101 is placed on a spinner 601 and rotated at a predetermined rotational speed. While the first substrate 101 rotates, an etching gas 603 such as fluorine-based gas to etch the oxide film is supplied from a nozzle 602 to the periphery 120 of the first substrate 101. Simultaneously, an inert gas 605 such as N₂ is supplied from a nozzle 604 to the central portion of the first substrate 101. When the etching gas 603 is supplied to the periphery 120 of the first substrate 101 while supplying the inert gas 605 to the central portion of the first substrate 101, the central portion of the first substrate 101 can be prevented from being etched by the etching gas 603. When the periphery 120 of the first substrate 101 is etched while rotating the first substrate 101, the insulating layer 102′ can be formed at the central portion of the first substrate 101.

The method of selectively removing the periphery 120 of the insulating layer 102 is not limited to the above-described methods. The first substrate 101 may be exposed by, e.g., arranging a mask at the central portion (region except the periphery 120) of the insulating layer 102 and etching the periphery 120 of the insulating layer 102 outside the mask. In this case, either wet etching or dry etching can be employed. Wet etching is more preferable because it can isotropically progress to make an angle a larger than 900. After the insulating layer 102′ is formed at the central portion of the first substrate 101, the mask is removed. As the material of the mask, for example, a photoresist can preferably be used. Instead of using a chemical solution or gas, the periphery 120 of the insulating layer 102 may be removed by, e.g., grinding.

If the angle α of the peripheral side surface of the insulating layer 102′ with respect to the exposed surface of the first substrate 101 is equal to or smaller than 90°, it is difficult to bond the substrates without any gap even when the first substrate 101 deforms. Hence, the angle α of the peripheral side surface of the insulating layer 102′ with respect to the exposed surface of the first substrate 101 preferably exceeds 90°. The angle α is more preferably 135° or more. That is, since the deformation amount of the second substrate 110 can be small, the angle α is preferably close to 180°.

In the step shown in FIG. 1C, the second substrate 110 is prepared. As the second substrate 110, an Si substrate, Ge substrate, SiGe substrate, SiC substrate, C substrate, GaAs substrate, GaN substrate, AlGaAs substrate, InGaAs substrate, InP substrate, InAs substrate, a substrate obtained by forming an insulating layer on these substrates, a transparent substrate such as a quartz substrate, or a sapphire substrate is preferable. However, the second substrate 110 only needs to have a sufficiently flat surface to be bonded and can be of any other type.

In the step shown in FIG. 1D, the first substrate 101 and second substrate 110 are bonded at room temperature while making the second substrate 110 face the insulating layer 102′, thereby forming a bonded substrate stack. The insulating layer 102′ can be formed on the first substrate 101, on the second substrate 110, or on both of them. It is only necessary that the state shown in FIG. 1D should be obtained when the first substrate 101 is bonded to the second substrate 110.

The entire surface of the first substrate 101 has undulation on several μm order so that a level difference of several ten to several nm is present. Hence, even when the periphery of the first substrate 101 has steps to some extent, they are absorbed by the undulation on the surface of the first substrate 101 or deformation of the first substrate 101. Hence, the substrates can be bonded without any gap. As the first substrate 101 becomes thin and easy to deform, and the bonding strength of the Si exposed portion at the periphery increases, the step absorbed by deformation of the first substrate 101 becomes large. Experimentally, a step of about 500 nm is absorbed. The insulating layer 102 is preferably thin. However, the present invention is not limited to this.

In the step shown in FIG. 1E, after the first substrate 101 and second substrate 110 are completely bonded, a process to make their bonding firm is executed. As an example of this process, preferably, 1) annealing is executed in an N₂ atmosphere at 1,100° C. for 10 min and 2) annealing (oxidation) is executed in an O₂/H₂ atmosphere at 1,100° C. for 50 to 100 min.

In the step shown in FIG. 1F, the first substrate 101 is planarized by grinding. With this process, an SOI substrate having a silicon layer on the insulating layer 102′ is obtained.

As described above, according to this embodiment, the periphery of the insulating layer of the first substrate is removed to expose the surface of the first substrate. Bonding is executed while keeping a step (e.g., several hundred nm) formed between the insulating layer surface and the first substrate surface. Hence, an SOI substrate whose insulating film is not exposed to the side surface can be manufactured by simple processes.

[Second Embodiment]

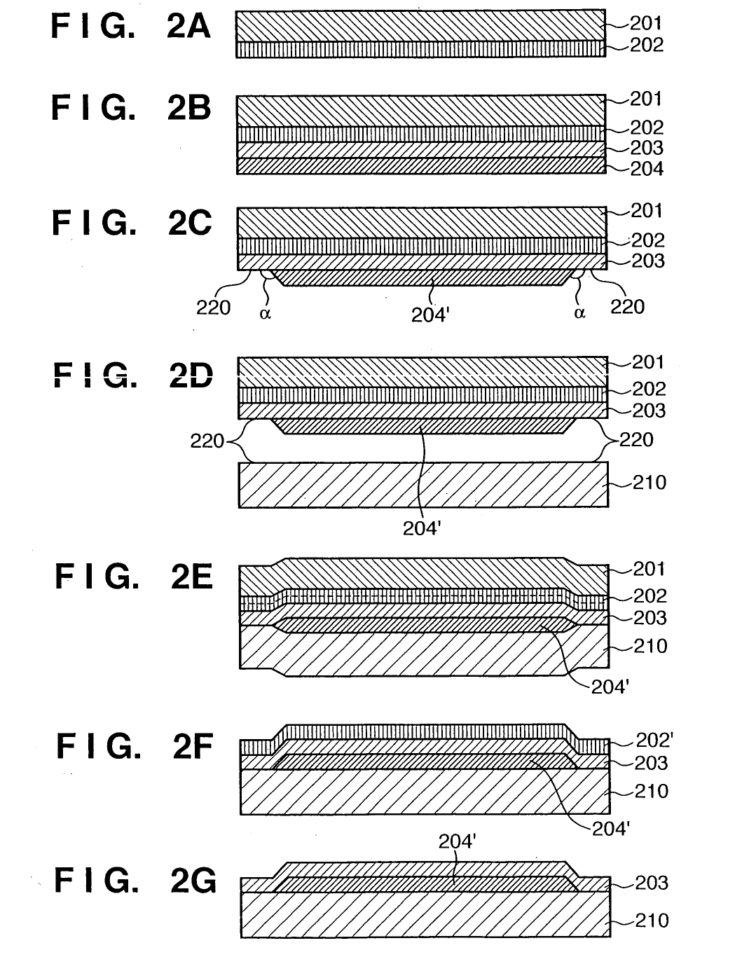

A substrate manufacturing method according to the second embodiment of the present invention will be described below. FIGS. 2A to 2G are sectional views showing the substrate manufacturing method according to the second embodiment of the present invention.

In the step shown in FIG. 2A, an Si substrate 201 is prepared. A porous Si layer 202 serving as a separation layer is formed on the major surface of the Si substrate 201. The porous Si layer 202 can be formed by, e.g., executing anodizing (anodic treatment) for the Si substrate 201 in an electrolyte (formation solution).

As the electrolyte, for example, a solution containing hydrogen fluoride, a solution containing hydrogen fluoride and ethanol, or a solution containing hydrogen fluoride and isopropyl alcohol is preferable. The porous Si layer 202 may have a multilayer structure including two or more layers having different porosities. The porous Si layer 202 having a multilayer structure preferably includes a first porous Si layer having a first porosity on the surface side, and a second porous Si layer having a second porosity higher than the first porosity under the first porous Si layer. The first porosity is preferably 10% to 30%, and more preferably, 15% to 25%. The second porosity is preferably 35% to 70%, and more preferably, 40% to 60%.

At the first stage of the step shown in FIG. 2B, a first non-porous layer 203 is formed on the porous Si layer 202. As the first non-porous layer 203, an Si layer such as a single-crystal Si layer, polysilicon layer, or amorphous Si layer, Ge layer, SiGe layer, SiC layer, C layer, GaAs layer, GaN layer, AlGaAs layer, InGaAs layer, InP layer, or InAs layer is preferable.

At the second stage of the step shown in FIG. 2B, an insulating layer 204 serving as a second non-porous layer is formed on the first non-porous layer 203. As the insulator material of the insulating layer 204, for example, silicon oxide, silicon nitride, silicon oxynitride, aluminum oxide, tantalum oxide, hafnium oxide, titanium oxide, scandium oxide, yttrium oxide, gadolinium oxide, lanthanum oxide, zirconium oxide, or a glass mixture thereof is preferable.

In the step shown in FIG. 2C, a periphery 220 of the insulating layer 204 is etched to expose the first non-porous layer 203 in accordance with the same procedures as in the step shown FIG. 1B.

In the step shown in FIG. 2D, a second substrate 210 is prepared. As the second substrate 210, an Si substrate, Ge substrate, SiGe substrate, SiC substrate, C substrate, GaAs substrate, GaN substrate, AlGaAs substrate, InGaAs substrate, InP substrate, InAs substrate, a substrate obtained by forming an insulating layer on these substrates, a transparent substrate such as a quartz substrate, or a sapphire substrate is preferable. However, the second substrate 210 only needs to have a sufficiently flat surface to be bonded and can be of any other type.

At the first stage of the step shown in FIG. 2E, the Si substrate 201 and second substrate 210 are bonded at room temperature while making the second substrate 210 face an insulating layer 204′. A process to make their bonding firm is executed. This process is executed in accordance with the same procedures as in the step shown FIG. 1E.

At the second stage of the step shown in FIG. 2E, the bonded substrate stack is split at the portion of the porous layer 202 having a low mechanical strength. Various kinds of methods can be employed for splitting. A method using a fluid is preferably used. For example, a fluid is injected into the porous layer 202, or a static pressure is applied to the porous layer 202 by a fluid.

With this splitting step, the non-porous layer 203 and insulating layer 204′ are transferred onto the second substrate 210.

In the step shown in FIG. 2F, a porous layer 202′ on the split second substrate 210 is selectively removed by etching. With this process, an SOI substrate having the non-porous layer 203 on the insulating layer 204′ can be obtained.

[Third Embodiment]

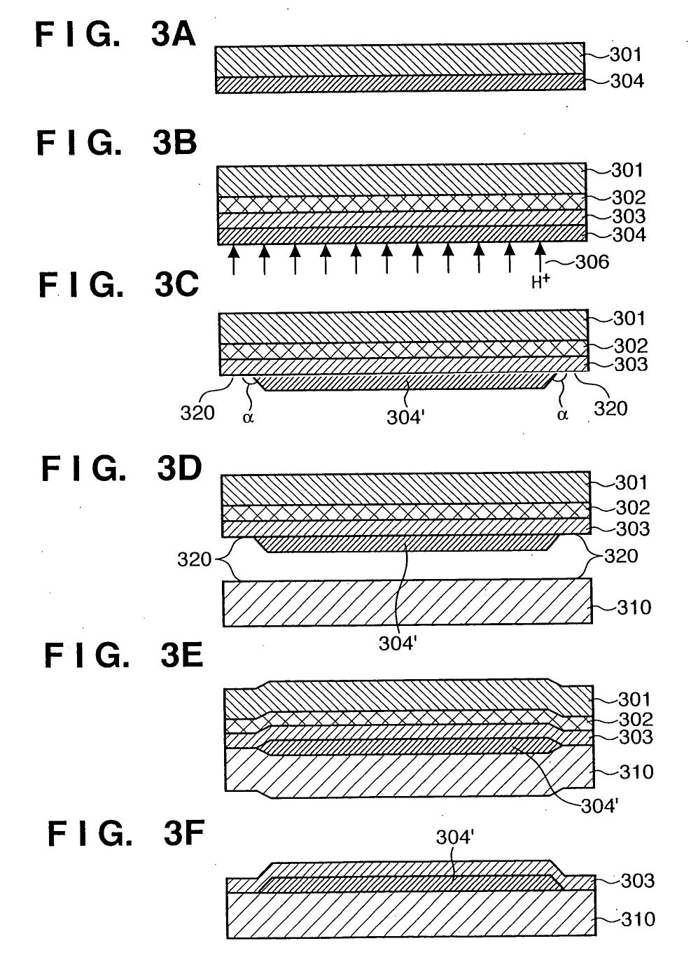

A substrate manufacturing method according to the third embodiment of the present invention will be described below. FIGS. 3A to 3F are sectional views showing the substrate manufacturing method according to the third embodiment of the present invention.

In the step shown in FIG. 3A, an Si substrate 301 is prepared. An insulating layer 304 is formed on the major surface of the Si substrate 301.

In the step shown in FIG. 3B, hydrogen ions 306 are implanted in the Si substrate 301. A micro-bubble layer 302 is formed at a predetermined depth in the Si substrate 301 by appropriately controlling the acceleration energy of the hydrogen ions. The surface portion of the Si substrate 301 changes to an Si layer 303.

In the step shown in FIG. 3C, a periphery 320 of the insulating layer 304 is etched to expose the first non-porous layer 303 in accordance with the same procedures as in the step shown FIG. 1B.

In the step shown in FIG. 3D, a second substrate 310 is prepared. As the second substrate 310, an Si substrate, Ge substrate, SiGe substrate, SiC substrate, C substrate, GaAs substrate, GaN substrate, AlGaAs substrate, InGaAs substrate, InP substrate, InAs substrate, a substrate obtained by forming an insulating layer on these substrates, a transparent substrate such as a quartz substrate, or a sapphire substrate is preferable. However, the second substrate 310 only needs to have a sufficiently flat surface to be bonded and can be of any other type.

In the step shown in FIG. 3E, the Si substrate 301 and second substrate 310 are bonded at room temperature while making the second substrate 310 face an insulating layer 304′. When the bonded substrate stack is subjected to annealing at 450° C. to 550° C., cleavage splitting occurs in the micro-bubble layer 302. Hence, the bonded substrate stack is split at the portion of the micro-bubble layer 302.

With this process, an SOI substrate having the non-porous layer 303 on the insulating layer 304′ can be obtained (FIG. 3F).

The present invention will be described below on the basis of examples. However, the present invention is not limited to these examples.

### EXAMPLE 1

FIGS. 1A to 1F show the substrate manufacturing method according to an example of the present invention. FIGS. 1A to 1F correspond to the substrate manufacturing method according to the first embodiment.

An Si substrate 101 having a thickness of 725 μm was prepared. Thermal oxidation was executed to form a 75-nm thick SiO₂ layer 102 on the surface of the Si substrate 101 (FIG. 1A).

The periphery of the SiO₂ film 102 was etched by a 0.7% hydrofluoric acid solution for 10 min by using any one of methods shown in FIG. 1B to form, at a 5-mm wide periphery, a region where the surface of the Si substrate 101 was exposed (FIG. 1B). Reference numeral 120 denotes a bonding region as the characteristic feature of the present invention.

The Si substrate 101 on the side of an SiO₂ layer 102′ was bonded to an Si substrate 110 (FIGS. 1C and 1D). The 75-nm step by the SiO₂ layer 102′ was absorbed by undulation on the Si surface or deformation of the Si substrate. Hence, the substrates could be bonded without any gap.

Annealing was executed at 1,000° C. for 130 min to completely bond the Si substrate 101 on the side of the SiO₂ layer 102′ and the Si substrate 110 (FIG. 1E).

The surface on the side of the Si substrate 101 was ground 715 μm by using a surface grinder. Next, mirror polishing was executed by using colloidal silica as abrasive grain. AN SOI wafer was obtained while leaving the Si film 101 having a thickness of 2 μm on the SiO₂ layer 102′ (FIG. 1F).

### EXAMPLE 2

FIGS. 2A to 2G show the substrate manufacturing method according to another example of the present invention. FIGS. 2A to 2G correspond to the substrate manufacturing method according to the second embodiment.

A p-type (100) Si substrate having a resistivity of 0.01 Ωcm was used as an Si substrate 201. After the Si substrate 201 was cleaned, anodizing was performed. Anodizing was executed in a solution mixture containing 49% hydrofluoric acid solution and alcohol solution at a ratio of 1:1 for 14 min at a current density of 10 mA/cm². The thickness of an porous Si layer 202 was 15 μm (FIG. 2A).

Annealing was executed in an oxygen atmosphere at 400° C. for 60 min to stabilize the surface of the porous Si layer 202. Si was epitaxially grown on the porous Si layer 202 to form a 1-μm thick epitaxial Si layer 203. To check the quality of crystal of the epitaxial layer 203, crystal defect evaluation was done by secco etching. However, no defects were observed.

The epitaxial Si layer 203 was thermally oxidized to form a 75-nm thick SiO₂ layer 204 on the epitaxial Si layer 203 (FIG. 2B).

The periphery of the SiO₂ film 204 was etched by a 0.7% hydrofluoric acid solution for 10 min by using any one of methods shown in FIG. 1B to form, at a 5-mm wide periphery, a region where the surface of the Si substrate 101 was exposed (FIG. 2C). Reference numeral 220 denotes a bonding region as the characteristic feature of the present invention.

The Si substrate 201 on the side of an SiO₂ layer 204′ was bonded to an Si substrate 210 (FIG. 2D). The 75-nm step at the periphery by the SiO₂ layer 204′ was absorbed by undulation on the Si surface or deformation of the Si substrate. Hence, the substrates could be bonded without any gap.

Annealing was executed at 1,000° C. for 130 min to completely bond the Si substrate 201 on the side of the SiO₂ film 204′ and the Si substrate 210. After that, the two wafers were split at the portion of the porous Si layer 202 by using a fluid wedge by water jet (FIG. 2E). A substrate having a structure including porous Si layer, epitaxial Si layer, thermal oxide layer, and Si substrate was obtained (FIG. 2F).

A porous Si layer 202′ was etched by using a solution mixture of hydrofluoric acid solution and hydrogen peroxide solution and applying an ultrasonic wave from the outside. The etching rate difference between the porous Si layer 202′ and the epitaxial Si layer 203 in this solution is about ×100,000. Hence, the porous Si layer 202′ could be etched without damaging the epitaxial Si layer 203. In this way, an SOI semiconductor which had the uniform epitaxial Si layer 203 and whose oxide film was not exposed to the outside could be manufactured (FIG. 2G).

In this example, the same effect as described above can be obtained even when the Si substrate 201 is thermally oxidized, and the periphery is etched to expose the surface of the Si substrate 201. In this example, the SiO₂ film 204 was obtained by oxidizing the epitaxial Si layer 203. However, the same effect as described above can be obtained even when the Si substrate 201 is also thermally oxidized, and its periphery is etched.

### EXAMPLE 3

FIGS. 3A to 3F show the substrate manufacturing method according to still another example of the present invention. FIGS. 3A to 3F correspond to the substrate manufacturing method according to the third embodiment.

An Si substrate 301 having a thickness of 725 μm was prepared. Thermal oxidation was executed to form a 500-nm thick SiO₂ layer 304 on the surface of the Si substrate 301 (FIG. 3A).

Hydrogen ions 306 were implanted from the surface of the substrate. A micro-bubble layer 302 was formed at a predetermined depth in the Si substrate by appropriately controlling the acceleration energy of the hydrogen ions 306. The surface portion of the Si substrate 301 changed to an Si layer 303 (FIG. 3B).

The periphery of the SiO₂ film 304 was etched by a 0.7% hydrofluoric acid solution for 10 min by using any one of methods shown in FIG. 1B to form, at a 5-mm wide periphery, a region where the surface of the Si substrate 301 was exposed (FIG. 3C). Reference numeral 320 denotes a bonding region as the characteristic feature of the present invention.

The Si substrate 301 on the side of an SiO₂ layer 304′ was bonded to an Si substrate 310 (FIGS. 3D and 3E). The 75-nm step by the SiO₂ layer 304′ was absorbed by undulation on the Si surface or deformation of the Si substrate. Hence, the substrates could be bonded without any gap.

When the bonded substrate stack was subjected to annealing at 450° C. to 550° C., cleavage splitting occurred in the micro-bubble layer 302. Hence, an SOI structure was formed on the side of the support substrate 310 (FIG. 3F).

In Examples 1 to 3, the SiO₂ film was etched by using a hydrofluoric acid solution. The same effect as described above can be obtained even when the periphery is removed by grinding.

As many apparently widely different embodiments of the present invention can be made without departing from the spirit and scope thereof, it is to be understood that the invention is not limited to the specific embodiments thereof except as defined in the claims.

Claim of Priority

This application claims priority from Japanese Patent Application No. 2004-161565 filed on May 31, 2004, which is hereby incorporated by reference herein.

1. A substrate manufacturing method comprising steps of:
preparing a first substrate which has a semiconductor and an insulating layer formed on a surface of the semiconductor;
selectively removing a periphery of the insulating layer to expose the semiconductor; and
bonding the first substrate on a side of the insulating layer to a second substrate to form a bonded substrate stack.

2. The method according to claim 1, wherein the semiconductor exposing step comprises a step of
supplying an etching solution to the periphery of the first substrate while rotating the first substrate.

3. The method according to claim 1, wherein the semiconductor exposing step comprises steps of
dipping the periphery of the first substrate in an etching solution, and rotating the first substrate.

4. The method according to claim 1, wherein the semiconductor exposing step comprises a step of
supplying an inert gas to a central portion of the first substrate while rotating the first substrate and simultaneously supplying an etching gas to the periphery of the first substrate.

5. The method according to claim 1, wherein the semiconductor exposing step comprises steps of
arranging a mask in a region except the periphery of the insulating layer, and
etching the periphery of the insulating layer on which no mask is arranged.

6. The method according to claim 1, wherein in the bonded substrate stack forming step, both the insulating layer and the exposed semiconductor are bonded to the second substrate.

7. The method according to claim 1, further comprising, after the bonded substrate stack forming step, a step of polishing a surface of the bonded substrate stack on a side of the first substrate.

8. The method according to claim 1, wherein in the first substrate preparation step, a substrate having a separation layer in the semiconductor is prepared as the first substrate.

9. The method according to claim 8, further comprising steps of
porosifying a surface of the semiconductor substrate to form the separation layer,
forming a semiconductor layer on a surface of the separation layer, and
forming an insulating layer on a surface of the semiconductor layer.

10. The method according to claim 8, further comprising a step of splitting the bonded substrate stack at a portion of the separation layer.

11. The method according to claim 1, further comprising, after the bonded substrate stack forming step, a step of annealing the bonded substrate stack.

12. The method according to claim 8, wherein the separation layer comprises an ion-implanted layer formed by implanting ions.

13. The method according to claim 1, wherein a thickness of the insulating layer is not more than 500 nm.

14. The method according to claim 1, wherein a peripheral side surface of the insulating layer removed in the semiconductor exposing step makes an angle of more than 90° with respect to the exposed semiconductor surface.
